(19) United States
(12) Patent Application Publication
(10) Pub. No.: US 2026/0153578 A1
(43) Pub. Date: Jun. 4, 2026

(54) SELF-SHAPING MAGNETIC RESONANCE LOCAL COIL

(71) Applicant: Siemens Healthineers AG, Forchheim (DE)

(72) Inventor: Vincent Kelber, Bamberg (DE)

(21) Appl. No.: 19/404,501

(22) Filed: Dec. 1, 2025

(30) Foreign Application Priority Data
Dec. 4, 2024 (DE) 10 2024 211 566.5

(51) Int. Cl. G01R 33/34

(52) U.S. Cl. CPC G01R 33/34084

(57) ABSTRACT

A magnetic resonance local coil and a magnetic resonance device, where the magnetic resonance local coil includes at least one antenna for transmitting and/or receiving radiofrequency signals and at least one bistable spring. In this arrangement the magnetic resonance local coil is configured to assume a curved shape in a first state of the bistable spring and a flat shape in a second state.

### CROSS REFERENCE TO RELATED APPLICATIONS

This application claims the benefit of DE 10 2024 211 566.5 filed on Dec. 4, 2024, which is hereby incorporated by reference in its entirety.

### FIELD

Embodiments relate to a magnetic resonance local coil and a magnetic resonance device.

### BACKGROUND

In the medical engineering sector, imaging by magnetic resonance (MR), also known as magnetic resonance tomography (MRT or MRI (Magnetic Resonance Imaging)), is characterized by high soft tissue contrasts. The process entails positioning an examination subject, a patient that is to be examined, for example, in an examination region of a magnetic resonance device for the purpose of a magnetic resonance measurement. During the magnetic resonance measurement, radiofrequency (RF) pulses and gradient pulses are generated with the aid of the magnetic resonance device in order to generate RF fields and magnetic field gradients in the examination region. This causes spatially encoded magnetic resonance signals to be triggered in the examination subject. The magnetic resonance signals are received by the magnetic resonance device and used for the reconstruction of magnetic resonance images.

For example, magnetic resonance local coils may be used for receiving the magnetic resonance signals. Local coils are often also referred to as surface coils. A magnetic resonance local coil is typically arranged in the immediate vicinity of the examination subject in order to keep the distance between the antennas of the magnetic resonance local coil and the source of the magnetic resonance signals as short as possible. This for example enables a high signal-to-noise ratio to be achieved for the magnetic resonance signals.

Known for example are magnetic resonance local coils that are configured in a blanket shape. However, as soon as it is desired to wrap such blanket-shaped magnetic resonance local coils around a part of the body (e.g. knee, elbow, etc.), additional fixing material (e.g. belt, adhesive tape), or a support or positioning aid into which the coil is placed and consequently is preshaped to conform to the body's geometry, is required.

### BRIEF SUMMARY AND DESCRIPTION

The scope of the present disclosure is defined solely by the claims and is not affected to any degree by the statements within this summary. The present embodiments may obviate one or more of the drawbacks or limitations in the related art. Independent of the grammatical term usage, individuals with male, female or other gender identities are included within the term.

Embodiments improve magnetic resonance local coils, for example to simplify their handling.

Embodiments provide a magnetic resonance local coil that includes at least one antenna for transmitting and/or receiving radiofrequency signals and at least one bistable spring. In this case, in a first state of the bistable spring, the magnetic resonance local coil is configured to possess, for example to assume, a curved shape.

In the first state of the bistable spring, the magnetic resonance local coil may be configured to wrap itself around an examination subject without an external application of force. The magnetic resonance local coil is advantageously (owing to the spring-loaded mode of operation of the bistable spring) a self-shaping magnetic resonance local coil.

The examination subject may be for example a part of the body of a patient. If the at least one bistable spring is in the first state, parts of the body having a substantially cylinder-shaped geometry, such as a knee, a wrist or an elbow for example, may be measured particularly effectively by the magnetic resonance local coil.

In a second state of the bistable spring, the magnetic resonance local coil may be configured to possess a flat shape. If the at least one bistable spring is in the second state, parts of the body having a substantially flat geometry, such as a torso for example, may be measured particularly effectively by the magnetic resonance local coil.

Bistable springs typically have two states of equilibrium. The first state of the at least one bistable spring of the magnetic resonance local coil may be one of the two states of equilibrium. The second state of the at least one bistable spring of the magnetic resonance local coil may be the other of the two states of equilibrium. With the aid of the at least one bistable spring, the magnetic resonance local coil may assume at least two different configurations, for example a curved and a flat configuration.

If the at least one bistable spring includes a plurality of bistable springs, it is conceivable that a first portion of the plurality of bistable springs is in the first state and at the same time a second portion of the plurality of bistable springs is in the second state. However, all of the bistable springs of the magnetic resonance local coil may be in the same state, i.e. all in the first state or all in the second state, during a magnetic resonance measurement with the aid of the magnetic resonance local coil.

If the at least one bistable spring includes a plurality of bistable springs, it is advantageous when the plurality of bistable springs are aligned substantially parallel to one another.

The at least one bistable spring may be for example a constant force spring. The at least one bistable spring may consist of layered flexible strips, for example.

During a transition from the first state into the second state, the at least one bistable spring may change its cross-sectional shape, for example from a convex shape to a concave shape, in at least one section. The change in cross-sectional shape advantageously produces a force shaping itself to fit the contour of the examination subject.

The magnetic resonance local coil, for example the at least one antenna, may be configured to be flexible, for example pliable. This enables the magnetic resonance local coil to shape itself particularly closely to fit the contour of the examination subject.

The at least one bistable spring may consist of an MR non-imaging material. As a result it may advantageously be achieved that the bistable spring itself is not imaged also in a magnetic resonance image. The MR non-imaging material includes carbon fiber, for example.

An embodiment of the magnetic resonance local coil provides that the magnetic resonance local coil includes a jacket, the at least one antenna being arranged inside the jacket. The at least one antenna may be protected with the aid of the jacket. For example, an ingress of fluids and/or contaminants may be prevented.

The jacket may include an outer covering layer, the at least one bistable spring being arranged on the outer covering layer. For example, the at least one bistable spring may be incorporated and/or integrated into the outer covering layer.

The distance between the at least one antenna and the examination subject may advantageously be minimized if the at least one bistable spring is arranged on the outer covering layer.

In the first state, the outer covering layer is advantageously located on the outward-facing side and/or surface of the magnetic resonance local coil. For example, the jacket of the magnetic resonance local coil includes an inner covering layer disposed opposite the outer covering layer, the at least one antenna being arranged between the outer and inner covering layer. The outer covering layer may be at a greater distance from the axis of curvature in the first state than the inner covering layer.

The outer covering layer is advantageously spaced further apart from the examination subject than an inner covering layer of the jacket disposed opposite thereto when the magnetic resonance local coil is arranged on the examination subject for the purpose of a magnetic resonance measurement.

A magnetic resonance device including an above-described magnetic resonance local coil is also provided. Features, advantages or alternative embodiments mentioned in this context may equally be applied also to the proposed magnetic resonance device, and vice versa.

### BRIEF DESCRIPTION OF THE FIGURES

FIG. 1 depicts a magnetic resonance device including a magnetic resonance local coil in a first state according to an embodiment.

FIG. 2 depicts a magnetic resonance device including a magnetic resonance local coil in a second state according to an embodiment.

FIG. 3 depicts a cross-section through a magnetic resonance local coil according to an embodiment.

FIG. 4 depicts a plan view onto a magnetic resonance local coil according to an embodiment.

### DETAILED DESCRIPTION

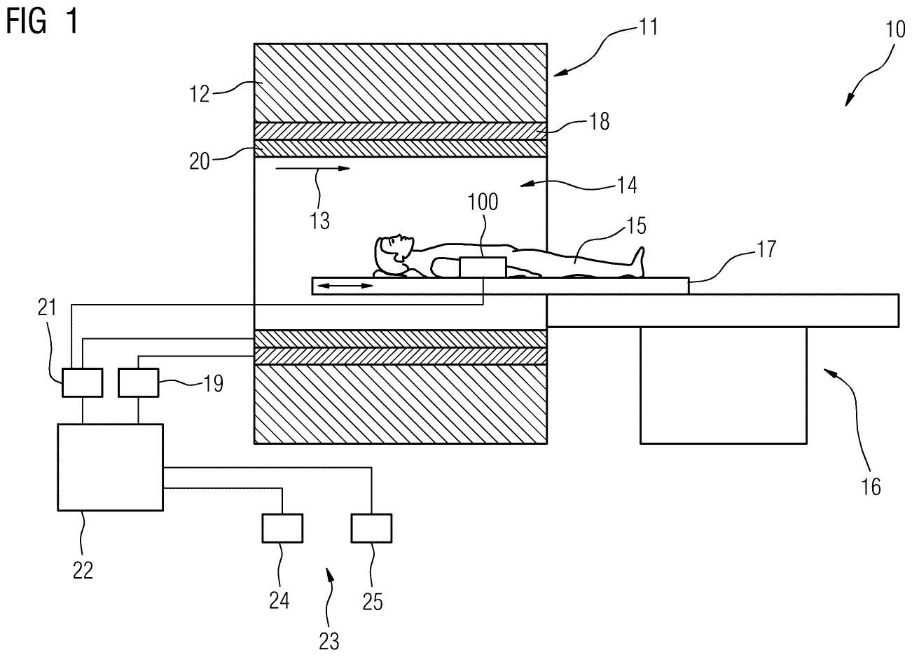

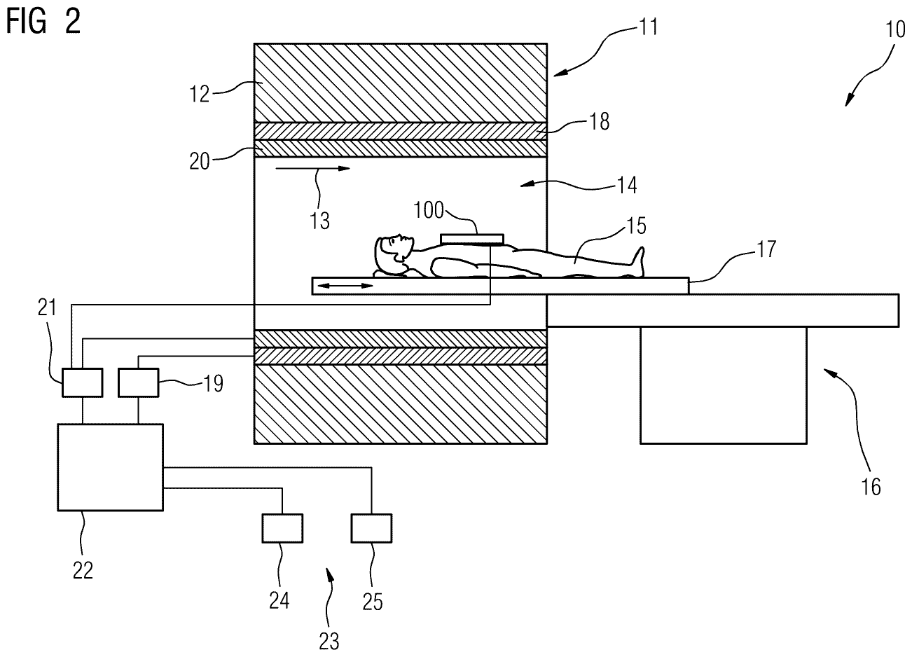

A magnetic resonance device 10 is represented schematically in FIG. 1 and FIG. 2. The magnetic resonance device 10 includes a magnet unit 11 that includes a main magnet 12 for generating a strong and for example temporally constant main magnetic field 13. The magnetic resonance device 10 further includes a patient receiving region 14 for accommodating a patient 15 as the examination subject. In the present embodiment, the patient receiving region 14 is configured in a cylinder shape and is cylindrically enclosed by the magnet unit 11 in a circumferential direction. However, an embodiment of the patient receiving region 14 differing therefrom is possible. The patient 15 may be introduced into the patient receiving region 14 by a patient positioning device 16 of the magnetic resonance device 10. For this purpose, the patient positioning device 16 includes a patient table 17 configured to be movable within the patient receiving region 14.

The magnet unit 11 additionally includes a gradient coil unit 18 for generating magnetic field gradients that are used for spatial encoding during an imaging procedure. The gradient coil unit 18 is controlled by a gradient control unit 19 of the magnetic resonance device 10. The magnet unit 11 further includes a radiofrequency antenna unit 20 which in the present embodiment is implemented as a bodycoil permanently integrated into the magnetic resonance device 10. The radiofrequency antenna unit 20 is controlled by a radiofrequency antenna control unit 21 of the magnetic resonance device 10 and radiates radiofrequency magnetic resonance sequences into an examination space that is substantially formed by a patient receiving region 14 of the magnetic resonance device 10. This causes an excitation of atomic nuclei to be induced in the main magnetic field 13 generated by the main magnet 12. Magnetic resonance signals are generated as a result of the relaxation of the excited atomic nuclei. The magnetic resonance device 10 further includes a magnetic resonance local coil 100 for receiving the magnetic resonance signals.

The magnetic resonance device 10 has a system control unit 22 for controlling the main magnet 12, the gradient control unit 19 and the radiofrequency antenna control unit 21. The system control unit 22 centrally controls the magnetic resonance device 10, such as the execution of a predetermined magnetic resonance imaging sequence, for example. The system control unit 22 further includes an evaluation unit (not shown in more detail) for evaluating the magnetic resonance signals acquired during the magnetic resonance examination. The magnetic resonance device 10 additionally includes a user interface 23 that is connected to the system control unit 22. Control information, such as imaging parameters, for example, as well as reconstructed magnetic resonance images, may be displayed on a display unit 24, for example on at least one monitor, of the user interface 23 for members of the medical operating staff. The user interface 23 also has an input unit 25 by which information and/or parameters may be input by the medical operating staff during a measurement procedure.

In FIG. 1, the magnetic resonance local coil 100 is situated in a first state in which the magnetic resonance local coil 100 has a curved shape and is wrapped around the elbow of the patient 15. In FIG. 2, the magnetic resonance local coil 100 is situated in a second state in which the magnetic resonance local coil 100 has a flat shape and is placed on the torso of the patient 15.

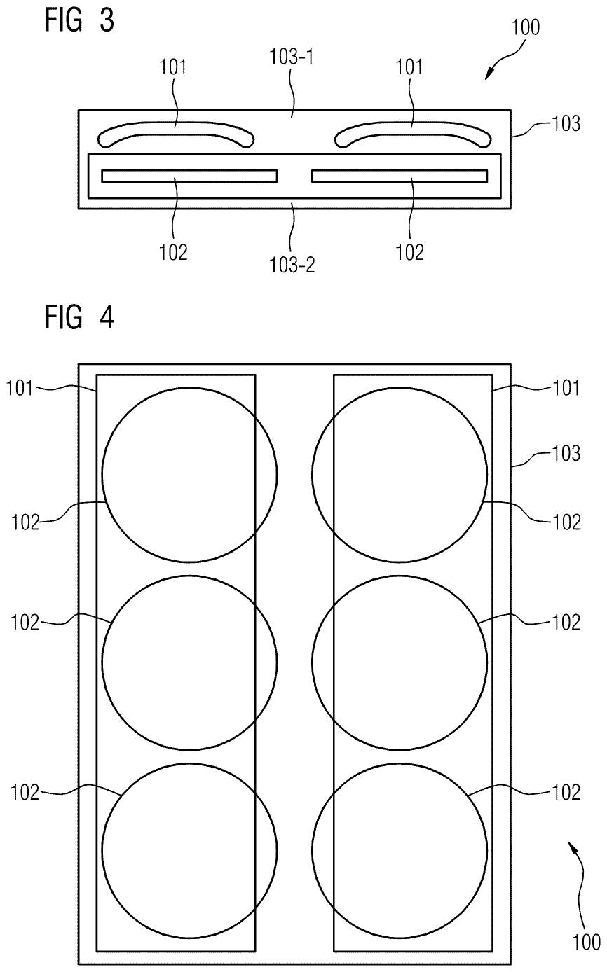

FIGS. 3 and 4 depict a possible magnetic resonance local coil 100 that may assume the states shown in FIGS. 1 and 2. For this purpose, in addition to six antennas 102 for transmitting and/or receiving radiofrequency signals, for example for receiving magnetic resonance signals, the magnetic resonance local coil 100 includes two bistable springs 101. In this example the bistable springs 101 and the antennas 102 are arranged in a jacket 103. The bistable springs 101 may be configured for example as a type of constant force spring. The bistable springs 101 may consist of a non-imaging material (e.g. carbon fiber).

In a first state of the bistable springs 101, the latter have a curved shape, thus enabling the magnetic resonance local coil 100 to mold itself for example around the elbow of the patient 15, as is shown in FIG. 1. In a second state of the bistable springs 101, the latter have a flat shape such that the magnetic resonance local coil 100 may be positioned for example on the upper body of the patient 15, as is shown in FIG. 2.

The magnetic resonance local coil 100 is advantageously constructed such that it wraps itself, as it were “automatically”, around a part of the body (e.g. knee, elbow, etc.) without an external application of force. This may be implemented for example such that the bistable springs 101 are incorporated in an outer covering layer 103-1 of the jacket 103. Located opposite is the inner covering layer 103-2, that is in direct contact with the examination subject or touches the latter.

The magnetic resonance local coil 100 may be electronically and mechanically constructed such that it is sufficiently flexible to emulate the preshaping of the bistable springs 101. Accordingly, they may remain in a flat state, as shown in FIG. 2. However, as soon as the magnetic resonance local coil 100 is placed for example around a somewhat cylinder-shaped examination subject, the magnetic resonance local coil 100 may automatically mold itself around the cylinder.

Advantageously, by an automatic “snapping” action of the magnetic resonance local coil 100, the latter may be optimally shaped to the contour of the examination subject that is to be measured. Furthermore, no additional fastenings such as belts or support and positioning aids are necessary any longer, thus enabling the operational workflow during a magnetic resonance examination to be improved, for example to be completed faster.

Furthermore, the magnetic resonance local coil 100 requires no additional fixing aids, that potentially may be difficult to clean and/or disinfect, so that the magnetic resonance local coil 100 may also be improved in terms of hygiene.

The magnetic resonance local coil 100 described in detail in the foregoing and the illustrated magnetic resonance device 10 are embodiments that may be modified in the most diverse ways by the person skilled in the art without leaving the scope of the invention. Furthermore, the use of the indefinite articles “a” or “an” does not rule out the possibility that the features in question may also be present more than once. Similarly, the term “unit” does not rule out the possibility that the components in question may consist of a plurality of cooperating subcomponents, that if necessary may also be spatially distributed.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that the dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A magnetic resonance local coil comprising:
at least one antenna for transmitting and/or receiving radiofrequency signals; and
at least one bistable spring;
wherein the magnetic resonance local coil is configured to assume a curved shape in a first state of the at least one bistable spring.

2. The magnetic resonance local coil of claim 1, wherein the magnetic resonance local coil is configured to be flexible.

3. The magnetic resonance local coil of claim 1, wherein the at least one antenna is configured to be flexible.

4. The magnetic resonance local coil of claim 1, wherein the magnetic resonance local coil is configured to wrap itself around an examination subject in the first state of the at least one bistable spring without an external application of force.

5. The magnetic resonance local coil of claim 1, wherein the magnetic resonance local coil is configured to assume a flat shape in a second state of the at least one bistable spring.

6. The magnetic resonance local coil of claim 1, wherein the at least one bistable spring consists of an MR non-imaging material.

7. The magnetic resonance local coil of claim 6, wherein the MR non-imaging material comprises carbon fiber.

8. The magnetic resonance local coil of claim 1, wherein the at least one bistable spring changes its cross-sectional shape during a transition between two states of equilibrium.

9. The magnetic resonance local coil of claim 1, wherein the magnetic resonance local coil comprises a jacket, wherein the at least one antenna is arranged inside the jacket.

10. The magnetic resonance local coil of claim 9, wherein the jacket comprises an outer covering layer, wherein the at least one bistable spring is arranged on the outer covering layer.

11. A magnetic resonance device comprising:
at least one magnetic resonance local coil comprising:
at least one antenna for transmitting and/or receiving radiofrequency signals; and
at least one bistable spring;
wherein the at least one magnetic resonance local coil is configured to assume a curved shape in a first state of the at least one bistable spring.
